(19) United States
(12) Patent Application Publication
(10) Pub. No.: US 2025/0153589 A1
(43) Pub. Date: May 15, 2025

(54) MOBILE CHARGING ROBOT AND AUTOMATIC CHARGING SYSTEM

(71) Applicants: Futaijing Precision Electronics (Yantai) Co., Ltd., Yantai (CN); HON Hai Precision Industry Co., Ltd., New Taipei (TW)

(72) Inventors: SHENG-LI YEN, New Taipei (TW); Chih-Cheng LEE, New Taipei (TW); Yu-Cheng ZHANG, New Taipei (TW); Chang-Ju Hsieh, New Taipei (TW); Chen CHAO, New Taipei (TW); Chen-Ting KAO, New Taipei (TW); Chiung-Hsiang WU, New Taipei (TW); Yi-Lun WEI, New Taipei (TW); Yu-Sheng CHANG, New Taipei (TW); Chi-Cheng WEN, New Taipei (TW)

(21) Appl. No.: 18/618,164

(22) Filed: Mar. 27, 2024

(30) Foreign Application Priority Data
Nov. 15, 2023 (CN) 202311527977.4

(51) Int. Cl. B60L 53/57; B60L 53/122; B60L 53/37; B60L 53/66; H02J 7/00; H02J 50/00; H02J 50/10; H02J 50/90; H05K 7/20

(52) U.S. Cl. CPC B60L 53/57; B60L 53/122; B60L 53/37; B60L 53/66; H02J 7/00032; H02J 7/0013; H02J 7/0042; H02J 50/005; H02J 50/10; H02J 50/90; H05K 7/209

(57) ABSTRACT

A mobile charging robot and an automatic charging system. The mobile charging robots include a battery assembly, a communication control assembly, a mobile body, and a wireless charging assembly. The battery assembly includes a plurality of energy storage elements for providing electrical energy. The plurality of energy storage elements is electrically connected to the communication control assembly. The mobile body includes a carrying platform. The battery assembly and the communication control assembly are mounted on the carrying platform. The mobile body is configured to carry the battery assembly to a specified location according to a command signal from the communication control assembly. One end of the wireless charging assembly is connected to the mobile body and is electrically connected to the battery assembly and the communication control assembly, the other end of the wireless charging assembly extends outwardly from one side of the mobile body for docking a to-be-charged device.

### FIELD

The present disclosure relates to field of charging equipment, and in particular to a mobile charging robot and automatic charging system.

### BACKGROUND

With the popularization of electric vehicles, the charging problem of electric vehicles is receiving more and more attention. In existing parking lots, fixed charging piles are usually set up in parking spaces, and cars need to be manually connected to the cable and charging plug in the corresponding parking spaces, and once a parking space with a charging pile is occupied, the charging pile will not be available, causing trouble to users. In addition, construction cost of charging piles is high, and it takes a long time to improve the configuration of charging piles in parking lots. How to improve the flexibility and convenience of car charging has become an urgent technical problem.

Thus, there is room for improvement within the art.

### BRIEF DESCRIPTION OF THE DRAWINGS

Many aspects of the disclosure can be better understood with reference to the following drawings. The assemblies in the drawings are not necessarily drawn to scale, the emphasis instead being placed upon clearly illustrating the principles of the disclosure. Moreover, in the drawings, like reference numerals designate corresponding parts throughout the several views.

FIG. 1 shows a schematic diagram illustrating a structure of a mobile charging robot according to an embodiment of the present application.

FIG. 2 shows a schematic diagram illustrating a structure of the mobile charging robot of FIG. 1 in another direction.

FIG. 3 shows a schematic diagram illustrating a structure of parts the mobile charging robot of FIG. 1.

FIG. 4 shows a schematic diagram illustrating a structure of a wireless charging assembly in the mobile charging robot of FIG. 1.

FIG. 5 shows a schematic diagram illustrating the structure of the wireless charging assembly in another direction.

FIG. 6 shows an explosion diagram of the mobile charging robot in FIG. 3.

FIG. 7 shows a schematic diagram illustrating a structure of an automatic charging system according to an embodiment of the present application.

### DETAILED DESCRIPTION

In order to make the above-mentioned objects, features and advantages of the present application more obvious, a detailed description of specific embodiments of the present application will be described in detail with reference to the accompanying drawings. A number of details are set forth in the following description so as to fully understand the present application. However, the present application can be implemented in many other ways different from those described herein, and those skilled in the art can make similar improvements without violating the contents of the present application. Therefore, the present application is not to be considered as limiting the scope of the embodiments described herein.

Several definitions that apply throughout this disclosure will now be presented.

The term “coupled” is defined as coupled, whether directly or indirectly through intervening assemblies, and is not necessarily limited to physical connections. The connection may be such that the objects are permanently coupled or releasably coupled. The term “substantially” is defined to be essentially conforming to the particular dimension, shape, or other feature that the term modifies, such that the assembly need not have that exact feature. The term “comprising,” when utilized, means “including, but not necessarily limited to;” it specifically indicates open-ended inclusion or membership in the so-described combination, group, series, and the like.

Unless otherwise defined, all technical and scientific terms used herein have the same meaning as commonly understood by one skilled in the art. The terms used in a specification of the present application herein are only for describing specific embodiments and are not intended to limit the present application. The terms “and/or” used herein includes any and all combinations of one or more of associated listed items.

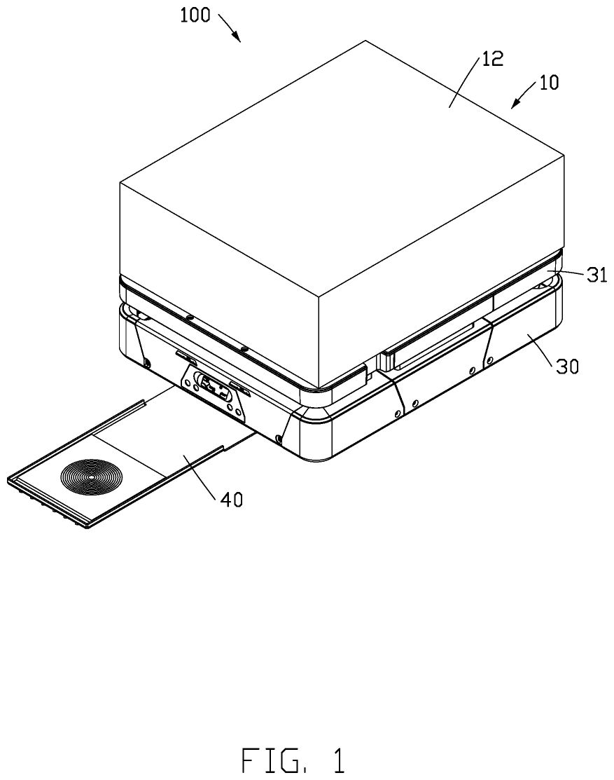

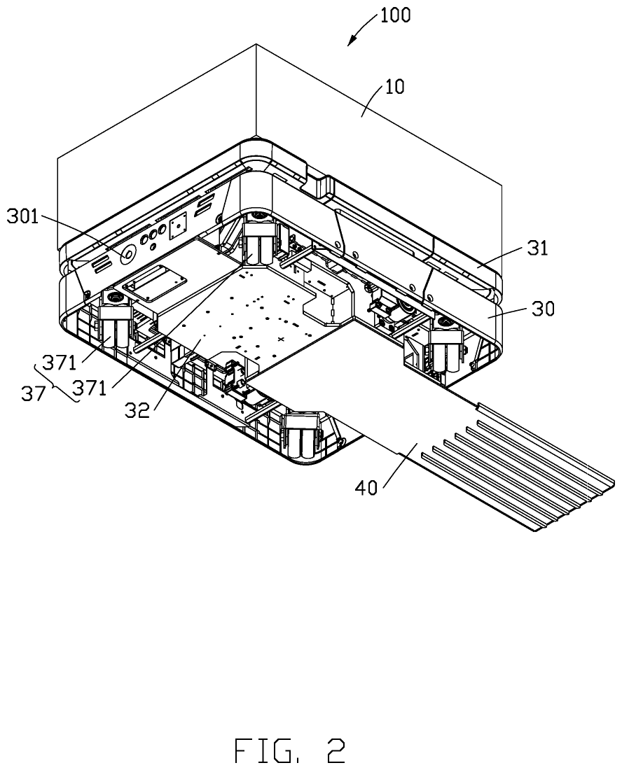

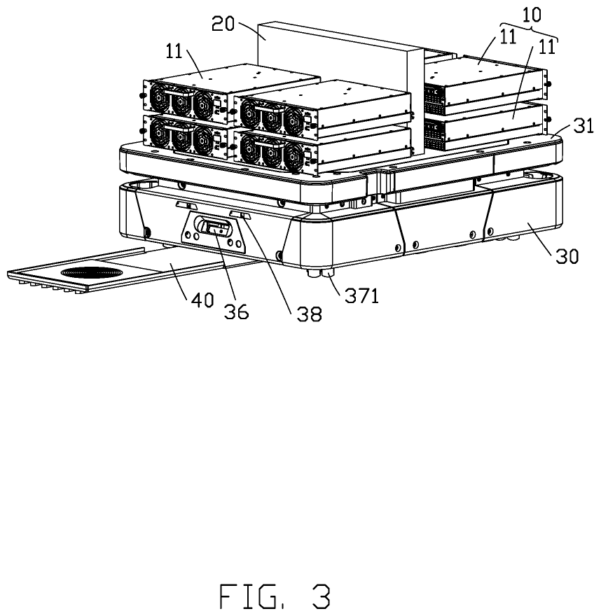

Referring to FIG. 1, FIG. 2, and FIG. 3, one embodiment provides a mobile charging robot 100 for automatically charging a vehicle, which can be applied in application scenarios such as a smart parking lot. The mobile charging robot 100 includes a battery assembly 10, a communication control assembly 20, a mobile body 30, and a wireless charging assembly 40. The battery assembly 10 includes a plurality of energy storage elements 11 for providing electrical energy. The communication control assembly 20 is disposed in the battery assembly 10, and the plurality of energy storage elements 11 are electrically connected to the communication control assembly 20. The mobile body 30 includes a carrying platform 31, the battery assembly 10 and the communication control assembly 20 are mounted on the carrying platform 31 and electrically connected to the mobile body 30. The mobile body 30 can carry the battery assembly 10 to a specified location according to a command signal from the communication control assembly 20. One end of the wireless charging assembly 40 is connected to a bottom of the mobile body 30 and is electrically connected to the battery assembly 10 and the communication control assembly 20, and another end of the wireless charging assembly 40 extends outwardly from one side of the mobile body 30 for receiving a to-be-charged device 201. The to-be-charged device 201 may be a transportation vehicle such as a car.

Through the signal interaction of the communication control assembly 20, the mobile charging robot 100 of the present application can move to the to-be-charged device 201 in a timely manner with a power supply to carry out an automatic charging operation, reducing the use of fixed charging piles, and being simple to operate and convenient to use.

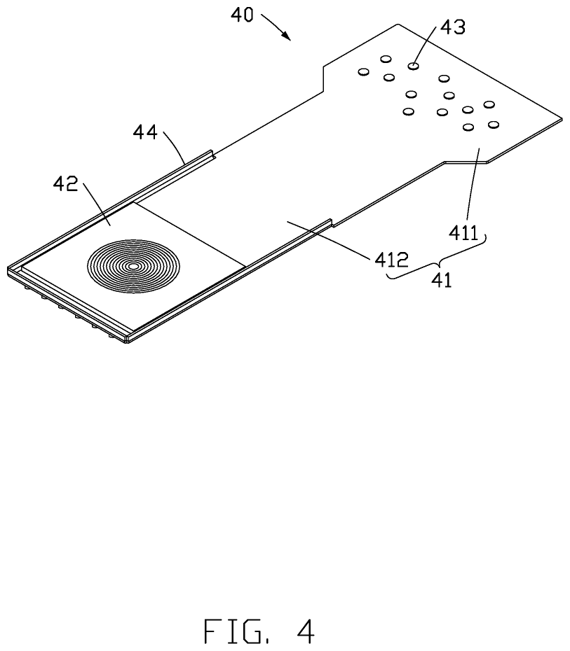

Referring to FIG. 4, in one embodiment, the wireless charging assembly 40 includes a mounting plate 41, a wireless charging inductor 42, and a connecting member 43. The mounting plate 41 includes a first portion 411 and a second portion 413. The first portion 411 is connected to the bottom of the mobile body 30, the second portion 413 extends outwardly from a side of the mobile body 30, and the second portion 413 is provided in an overhead position. A connection member 43 is provided at the first portion 411, and the connection member 43 may be a plurality of connection PIN pins, or may be an electrical connector or an electrical connection port. The wireless charging inductor 42 is provided in the second portion 413, and the mounting plate 41 further includes a built-in circuit structure to electrically connect the wireless charging inductor 42 and the connection member 43. The connection member 43 is electrically connected to the communication control assembly 20 and the battery assembly 10 to conduct the wireless charging inductor 42 and the battery assembly 10, so as to enable the wireless charging inductor 42 to provide power to the to-be-charged device 201.

Furthermore, a width of the first portion 411 is greater than a width of the second portion 413 to increase a connection area between the mounting plate 41 and the mobile body 30 and improve connection strength. The second portion 413 is also provided with a flange structure 44 on sides of the second portion 413, and the wireless charging inductor 42 is provided on an upper surface of the second portion 413 and is located in a space formed in the flange structure 44. A height of the flange structure 44 is greater than or equal to a thickness of the wireless charging inductor 42, thereby playing a role in protecting the wireless charging inductor 42 and reducing cuts and damages to the wireless charging inductor 42 during movement of the robot.

Referring to FIG. 2, the bottom of the mobile body 30 is provided with a lifting chassis 32. The first portion 411 of the mounting plate 41 is connected to the lifting chassis 32. The lifting chassis 32 can drive the mounting plate 41 up and down to adapt charging positions at different heights, to meet with charging needs of vehicles at different heights.

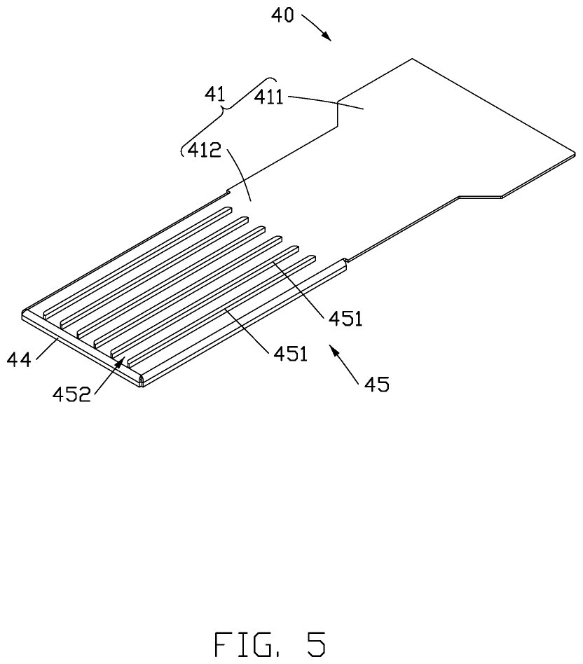

Referring to FIG. 5, in an embodiment, the wireless charging assembly 40 further includes a heat dissipation assembly, the heat dissipation assembly is provided on the side of the mounting plate 41 back away from the wireless charging inductor 42 and is provided in correspondence with the wireless charging inductor 42. The heat dissipation assembly is configured to cool down the wireless charging inductor 42 and reduce the heating temperature during the charging process. The heat dissipation assembly includes a plurality of fins 451, which are provided on the side of the second portion 413 that is away from the wireless charging inductor 42. The plurality of fins 451 are spaced apart, and a heat dissipation channel 452 is formed between adjacent fins 451. The heat generated by the wireless charging inductor 42 may be conducted to the plurality of fins 451 through the second portion 413, and the heat dissipation airflow takes away heat from the plurality of fins 451 when flowing through the heat dissipation channel 452, to achieve the heat reduction temperature of the wireless charging inductor 42, thereby achieving a heat dissipation effect.

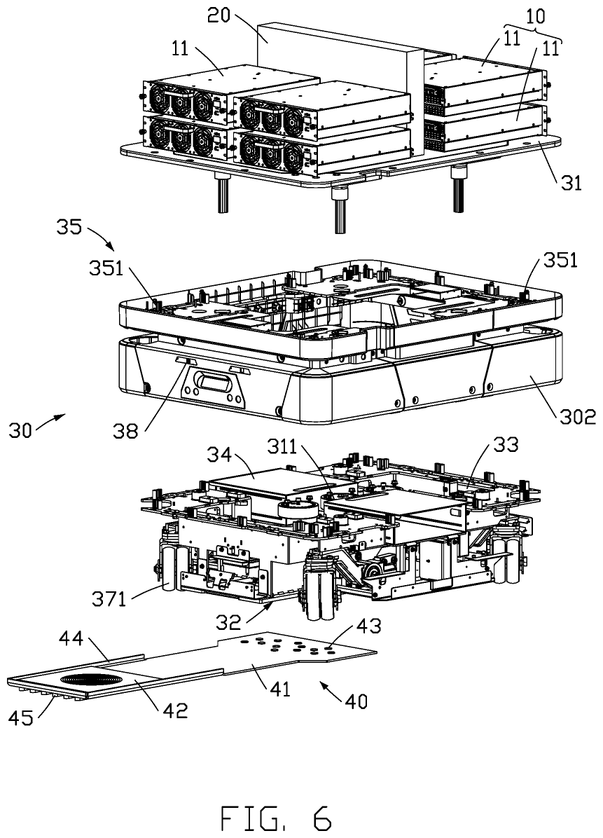

Referring to FIG. 3 and FIG. 6, the carrying platform 31 is disposed on top of the mobile body 30, and the communication control assembly 20 is disposed in a central region of the carrying platform 31. A connector 311 is also provided on the carrying platform 31 at a position corresponding to the communication control assembly 20. The connector 311 may be partially provided inside the mobile body 30 and electrically connected to an internal circuit assembly of the mobile body 30. A bottom portion of the communication control assembly 20 is plugged with the connector 311 to electrically connect the communication control assembly 20 to the mobile body 30. A plurality of energy storage elements 11 are stacked on the carrying platform 31 and distributed on opposite sides of the communication control assembly 20. The plurality of energy storage elements 11 are electrically connected to the communication control assembly 20 in parallel or in series. The battery assembly 10 also includes a protective case 12. The protective case 12 is detachably mounted on the carrying platform 31, and the communication control assembly 20 and the plurality of energy storage elements 11 are received in the protective case 12. When the power of one or more of the energy storage elements 11 is exhausted and needs to be replaced, the protective case 12 can be opened and the energy storage elements 11 can be replaced by pulling and extracting the energy storage elements 11. In other embodiments, a charging interface 301 can be provided on the mobile body 30, and the plurality of energy storage elements 11 can be electrically connected to the charging interface 301 through the communication control assembly 20, and an external power source can be provided to the plurality of energy storage elements 11 through the charging interface 301. The plurality of energy storage elements 11 may be electrically connected to the charging interface 301 via the communication control assembly 20, and an external power source may also be able to supplement the plurality of energy storage elements 11 from the charging interface 301.

Furthermore, the mobile body 30 further includes a fuselage body 33, a drive control assembly 34, a moving assembly 37, and a shell 302. The drive control assembly 34 is fixedly mounted on the fuselage body 33, and the communication control assembly 20 is electrically connected to the drive control assembly 34. The moving assembly 37 and the lifting chassis 32 are mounted on the bottom of the fuselage body 33, and the shell 302 is disposed outside the fuselage body 33, with the moving assembly 37 partially exposed to the shell 302, and the moving assembly 37 partially exposed to the shell 302. The moving assembly 37 is partially exposed at the bottom of the shell 302. The drive control assembly 34 is electrically connected to the moving assembly 37. The drive control assembly 34 can drive the moving assembly 37 according to the interactive commands of the communication control assembly 20, so as to move the mobile charging robot 100 to a specified position. The moving assembly 37 includes a plurality of roller mechanisms 371, the plurality of roller mechanisms 371 are symmetrically distributed on the peripheral side of the fuselage body 33, and the lifting chassis 32 is located between the plurality of roller mechanisms 371. The drive control assembly 34 may also be electrically connected to the lifting chassis 32 to control upward and downward movement of the wireless charging assembly 40.

Furthermore, the mobile body 30 further includes a radar assembly 35 and a sensor 38. The radar assembly 35 is mounted on a side of the shell 302. The radar assembly 35 includes a first radar 351 and a second radar 352. The first radar 351 and the second radar 352 are respectively located on opposing sides of the shell 302, for detecting orientation of the robot and the to-be-charged device 201. In some embodiments of the present application, the first radar 351 and the second radar 352 are diagonally distributed around the circumference of the shell 302. In other embodiments, the number of the first radar 351 and the second radar 352 may also be two or more, and multiple first radars 351 and multiple second radars 352 are symmetrically distributed on the circumferential side of the shell 302 for comprehensively detecting the orientation of the robot and the to-be-charged device 201. The sensor 38 is mounted on the side of the shell 302 facing the wireless charging assembly 40 for detecting the distance between the robot and the to-be-charged device 201 and determining whether the robot has arrived at the designated position. The radar assembly 35 and the sensor 38 are electrically connected to the communication control assembly 20 to transmit the detection signals to the communication control assembly 20. The communication control assembly 20 may actuate the orientation and characteristics of the to-be-charged device 201 based on the detection signals of the radar assembly 35 and the sensor 38, to calculate data of the center position of the to-be-charged device 201, and then set a distance for the robot to approach the to-be-charged device 201 based on the calculated data of the center position, so that the robot will be able to reach the specified position. So that the wireless charging assembly 40 smoothly receives the to-be-charged device 201, for charging.

When the mobile charging robot 100 is in the process of approaching the to-be-charged device 201, the sensor 38 may detect and compare the distance between the robot and the to-be-charged device 201 in real time to determine whether the detection distance reaches a set distance, and the communication control assembly 20 may adjust the operation state of the mobile body 30 according to the detection results of the sensor 38. Characterization information of the to-be-charged device 201 may also be input into the communication control assembly 20 via external mobile terminal 203 to enhance the charging success rate of the mobile charging robot 100.

In some embodiments of the present application, the mobile body 30 may further include a visual detection assembly 36. The visual detection assembly 36 is disposed on the side of the fuselage body 33 towards the wireless charging assembly 40, and the visual detection assembly 36 is electrically connected to the communication control assembly 20 for detecting the surrounding environment of the robot and feeding back signals to the communication control assembly 20 so that the communication control assembly 20 adjusts the robot's movement path.

Furthermore, a variety of maps may also be pre-stored in the communication control assembly 20 or/and the drive control assembly 34. The mobile charging robot 100 may quickly switch the corresponding maps in different usage scenarios to match the current usage environment, enhancing the versatility of the mobile charging robot 100. In other embodiments, a map within the mobile range of the robot may also be drawn and saved in the communication control assembly 20 or/and the drive control assembly 34 based on the detection results of the radar assembly 35, the sensors 38, the visual detection assembly 36.

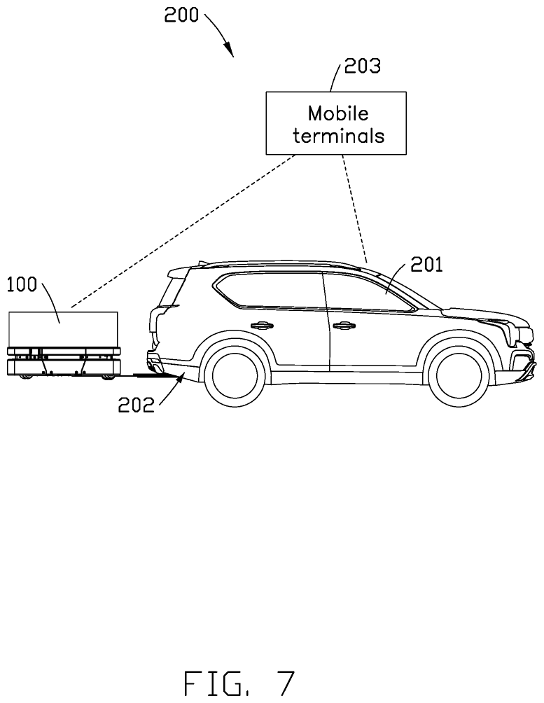

Referring to FIG. 7, embodiments of the present application also provide an automatic charging system 200 including a to-be-charged device 201 and a mobile charging robot 100 as described in the above embodiments. The to-be-charged device 201 is communicatively connected to the communication control assembly 20 of the mobile charging robot 100. The communication control assembly 20 docking the wireless charging assembly 40 with the to-be-charged device 201 based on the interaction signal of the to-be-charged device 201, to provide electrical energy to the to-be-charged device 201. The to-be-charged device 201 may be a transportation vehicle such as a car. The bottom of the to-be-charged device 201 is configured with an inductive assembly 202. When the mobile charging robot 100 moves to a designated position, the wireless charging assembly 40 may be partially inserted under the bottom of the to-be-charged device 201, and the inductive assembly 202 is paired with the wireless charging inductor 42 of the wireless charging assembly 40 to carry out charging by means of magnetic induction.

Furthermore, the automatic charging system 200 may also include a mobile terminal 203, the mobile terminal 203 communicatively connecting the to-be-charged device 201 and the mobile charging robot 100, so that the user may remotely control the charging process of the mobile charging robot 100 towards the to-be-charged device 201 via the mobile terminal 203, to enhance the user's operational convenience. In one embodiment of the present application, the mobile body 30 can carry objects of 1000 kg. So that the mobile body 30 can carry the battery assembly 10 and the wireless charging assembly 40 with sufficient power. The mobile body 30 is connected to the mobile body 30 through the communication control assembly 20, so that the mobile charging robot 100 can move the wireless charging assembly 40 to a position docked to the car coil according to external command or the detection result of the mobile body 30, and use the magnetic induction method to charge the vehicle, and the whole charging process is carried out automatically, which is simple to operate and does not require the driver to get out of the vehicle to operate, and effectively improves user experience. In addition, the mobile charging robot 100 of the present application can be expanded based on a logistics robot, and can be used in multiple fields, switching map at any time to meet different needs.

It is to be understood, even though information and advantages of the present embodiments have been set forth in the foregoing description, together with details of the structures and functions of the present embodiments, the disclosure is illustrative only; changes may be made in detail, especially in matters of shape, size, and arrangement of parts within the principles of the present embodiments to the full extent indicated by the plain meaning of the terms in which the appended claims are expressed.

What is claimed is:

1. A mobile charging robot, comprising:
a battery assembly, the battery assembly comprises a plurality of energy storage elements,
a communication control assembly, the communication control assembly is positioned in the battery assembly, the plurality of energy storage elements is electrically connected to the communication control assembly,
a mobile body, the mobile body comprises a carrying platform, the battery assembly and the communication control assembly are arranged on the carrying platform and electrically connected to the mobile body, the mobile body is configured to carry the battery assembly to a specified location in accordance with a command signal from the communication control assembly, and
a wireless charging assembly, the wireless charging assembly is electrically connected to the battery assembly and the communication control assembly, one end of the wireless charging assembly is connected to the mobile body and is electrically connected to the battery assembly and the communication control assembly, another end of the wireless charging assembly extends outwardly from one side of the mobile body for docking a to-be-charged device.

2. The mobile charging robot as claimed in claim 1, wherein the wireless charging assembly comprises a mounting plate, a wireless charging inductor, and a connecting member, the mounting plate comprises a first portion and a second portion, the first portion is connected to a bottom of the mobile body, the second portion extends outwardly from a side of the mobile body, and the second portion is provided in an overhanging position; the connecting member is disposed on the first portion, the connecting member is electrically connected to the communication control assembly and the battery assembly, the wireless charging inductor is disposed on the second portion, the wireless charging inductor is electrically connected to the connecting member.

3. The mobile charging robot as claimed in claim 2, wherein the second portion is provided with a flange structure on sides of the second portion, the wireless charging inductor is provided on an upper surface of the second portion and is located within a space formed by enclosure of the flange structure, a height of the flange structure is greater than or equal to a thickness of the wireless charging inductor.

4. The mobile charging robot as claimed in claim 2, wherein a lifting chassis is provided at the bottom of the mobile body, the first portion of the mounting plate is connected to the lifting chassis, and the lifting chassis drives the mounting plate up and down.

5. The mobile charging robot as claimed in claim 2, wherein the wireless charging assembly further comprises a heat dissipation assembly, the heat dissipation assembly comprises a plurality of fins, the plurality of fins is disposed on a side of the second portion back away from the wireless charging inductor, each of the plurality of fins is disposed at intervals, and a heat dissipation channel is formed between adjacent fins of the plurality of fins.

6. The mobile charging robot as claimed in claim 1, wherein the carrying platform is located on top of the mobile body, the plurality of energy storage elements are stacked on the carrying platform and are disposed on opposite sides of the communication control assembly, the battery assembly further comprises a protective case, the protective case is removably mounted on the carrying platform, the communication control assembly and the plurality of energy storage elements are received in the protective case.

7. The mobile charging robot as claimed in claim 1, wherein the mobile body further comprises a fuselage body, a drive control assembly, a moving assembly, and a shell, the drive control assembly is fixedly mounted to the fuselage body, the communication control assembly is electrically connected to the drive control assembly, the moving assembly is mounted to a bottom of the fuselage body, the shell is provided on an outside of the fuselage body, the moving assembly partially exposed at the bottom of the shell, and the drive control assembly is electrically connected to the moving assembly, the moving assembly is driven to run by the drive control assembly according to interactive commands of the communication control assembly.

8. The mobile charging robot as claimed in claim 7, wherein the mobile body further comprises a radar assembly, the radar assembly is electrically connected to the communication control assembly; the radar assembly comprises a first radar and a second radar, the first radar and the second radar are respectively disposed on opposite sides of the shell for detecting orientation of the mobile charging robot and a to-be-charged device.

9. The mobile charging robot as claimed in claim 7, wherein the mobile body further comprises a visual detection assembly and a sensor provided on a side of the fuselage body facing the wireless charging assembly, the visual detection assembly and the sensor are electrically connected to the communication control assembly, the visual detection assembly detects robot's surroundings, and the sensor detects a distance between the mobile charging robot and a to-be-charged device for determining whether or not the mobile charging robot has arrived at a specified position.

10. An automatic charging system, comprising:
a to-be-charged device, and
a charging robot, wherein the charging robot comprises:
a battery assembly, the battery assembly comprises a plurality of energy storage elements,
a communication control assembly, the communication control assembly is positioned in the battery assembly, the plurality of energy storage elements is electrically connected to the communication control assembly,
a mobile body, the mobile body comprises a carrying platform, the battery assembly and the communication control assembly are arranged on the carrying platform and electrically connected to the mobile body, the mobile body is configured to carry the battery assembly to a specified location in accordance with a command signal from the communication control assembly, and
a wireless charging assembly, the wireless charging assembly is electrically connected to the battery assembly and the communication control assembly, one end of the wireless charging assembly is connected to the mobile body and is electrically connected to the battery assembly and the communication control assembly, another end of the wireless charging assembly extends outwardly from one side of the mobile body;
the to-be-charged device is communicatively connected to the communication control assembly of the mobile charging robot, the communication control assembly is configured to dock the wireless charging assembly with the to-be-charged device based on an interaction signal from the to-be-charged device to provide electrical energy to the to-be-charged device.

11. The automatic charging system as claimed in claim 10, wherein the wireless charging assembly comprises a mounting plate, a wireless charging inductor, and a connecting member, the mounting plate comprises a first portion and a second portion, the first portion is connected to a bottom of the mobile body, the second portion extends outwardly from a side of the mobile body, and the second portion is provided in an overhanging position; the connecting member is disposed on the first portion, the connecting member is electrically connected to the communication control assembly and the battery assembly, the wireless charging inductor is disposed on the second portion, the wireless charging inductor is electrically connected to the connecting member.

12. The automatic charging system as claimed in claim 11, wherein the second portion is provided with a flange structure on sides of the second portion, the wireless charging inductor is provided on an upper surface of the second portion and is located within a space formed by enclosure of the flange structure, a height of the flange structure is greater than or equal to a thickness of the wireless charging inductor.

13. The automatic charging system as claimed in claim 11, wherein a lifting chassis is provided at the bottom of the mobile body, the first portion of the mounting plate is connected to the lifting chassis, and the lifting chassis drives the mounting plate up and down.

14. The automatic charging system as claimed in claim 11, wherein the wireless charging assembly further comprises a heat dissipation assembly, the heat dissipation assembly comprises a plurality of fins, the plurality of fins is disposed on a side of the second portion back away from the wireless charging inductor, each of the plurality of fins is disposed at intervals, and a heat dissipation channel is formed between adjacent fins of the plurality of fins.

15. The automatic charging system as claimed in claim 10, wherein the carrying platform is located on top of the mobile body, the plurality of energy storage elements are stacked on the carrying platform and are disposed on opposite sides of the communication control assembly, the battery assembly further comprises a protective case, the protective case is removably mounted on the carrying platform, the communication control assembly and the plurality of energy storage elements are received in the protective case.

16. The automatic charging system as claimed in claim 10, wherein the mobile body further comprises a fuselage body, a drive control assembly, a moving assembly, and a shell, the drive control assembly is fixedly mounted to the fuselage body, the communication control assembly is electrically connected to the drive control assembly, the moving assembly is mounted to a bottom of the fuselage body, the shell is provided on an outside of the fuselage body, the moving assembly partially exposed at the bottom of the shell, and the drive control assembly is electrically connected to the moving assembly, the moving assembly is driven to run by the drive control assembly according to interactive commands of the communication control assembly.

17. The automatic charging system as claimed in claim 16, wherein, the mobile body further comprises a radar assembly, the radar assembly is electrically connected to the communication control assembly; the radar assembly comprises a first radar and a second radar, the first radar and the second radar are respectively disposed on opposite sides of the shell for detecting orientation of the mobile charging robot and a to-be-charged device.

18. The automatic charging system as claimed in claim 16, wherein the mobile body further comprises a visual detection assembly and a sensor provided on a side of the fuselage body facing the wireless charging assembly, the visual detection assembly and the sensor are electrically connected to the communication control assembly, the visual detection assembly detects robot's surroundings, and the sensor detects a distance between the mobile charging robot and a to-be-charged device for determining whether or not the mobile charging robot has arrived at a specified position.
